(19) United States
(12) Patent Application Publication
(10) Pub. No.: US 2017/0064821 A1
(43) Pub. Date: Mar. 2, 2017

(54) ELECTRONIC PACKAGE AND METHOD FORMING AN ELECTRICAL PACKAGE

(71) Applicants: Kristof Darmawikarta, Chandler, AZ (US); Daniel Sobieski, Phoenix, AZ (US); Kyu Oh Lee, Chandler, AZ (US); Sri Ranga Sai Boyapati, Chandler, AZ (US)

(72) Inventors: Kristof Darmawikarta, Chandler, AZ (US); Daniel Sobieski, Phoenix, AZ (US); Kyu Oh Lee, Chandler, AZ (US); Sri Ranga Sai Boyapati, Chandler, AZ (US)

(21) Appl. No.: 14/840,979

(22) Filed: Aug. 31, 2015

(51) Int. Cl. H05K 1/02; H05K 3/00; H05K 3/40; H05K 3/18; H05K 1/11; H05K 3/46

(52) U.S. Cl. CPC H05K 1/0298; H05K 1/113; H05K 3/4644; H05K 3/4038; H05K 3/181; H05K 3/188; H05K 3/0041; H05K 2201/09218; H05K 2201/09654; H05K 2201/09372; H05K 2201/095; H05K 2203/0548

(57) ABSTRACT

Some example forms relate to an electronic package. The electronic package includes a first dielectric layer that includes an electrical trace formed on a surface of the first dielectric layer and a second dielectric layer on the surface of the first dielectric layer. The second dielectric layer includes an opening. The electrical trace is within the opening. The electronic package includes an electrical interconnect that fills the opening and extends above an upper surface of the second dielectric layer such that the electrically interconnect is electrically connected to the electrical trace on the first dielectric layer.

### BACKGROUND

FIG. 1 schematic top view that includes microvias 1, conductive pads 2 and conductive traces 3 that may be used within a conventional electronic package 4. In most conventional electronic packages, laser drilling is used to form microvias that provide electrical connections between the metallization (copper) layers in the electronic packages.

Electronic package real estate is mainly dictated by pad sizes as well as electrical trace width and the spacing between electrical traces. Pad size is typically determined by (i) the underlying uVia size; and (ii) via to pad alignment (see, e.g., FIG. 1).

As an example, with a 9/12 um trace width and trace spacing the pad diameter may be 77 um and the via diameter is 49 um. This means that the underlying process that is used to fabricate this particular configuration must have an alignment capability that is 14 um or less.

Minimizing via size is desirable in order to meet the increasing demand for higher density routing. However, minimizing via size may be quite challenging due to reliability concerns.

### BRIEF DESCRIPTION OF THE DRAWINGS

FIG. 1 illustrates an example prior art electronic package.

FIG. 2 shows a schematic top and side view illustrating a portion of an example electronic package.

FIGS. 3A, 3B illustrate example steps for making an electronic package similar to the electronic package shown in FIG. 2.

FIG. 4 shows a schematic top and side view illustrating a portion of another example electronic package that includes non-circular vias and non-circular pads.

FIG. 5 illustrates example steps for making an electronic package similar to the electronic package shown in FIG. 4.

FIG. 6 is a top view illustrating another example electronic package that includes non-circular vias and non-circular pads.

FIG. 7 is a flow diagram illustrating an example method of forming an electronic package.

FIG. 8 is a flow diagram illustrating another example method of forming an electronic package.

FIG. 9 is block diagram of an electronic apparatus that includes the electrical interconnects and/or electronic packages described herein.

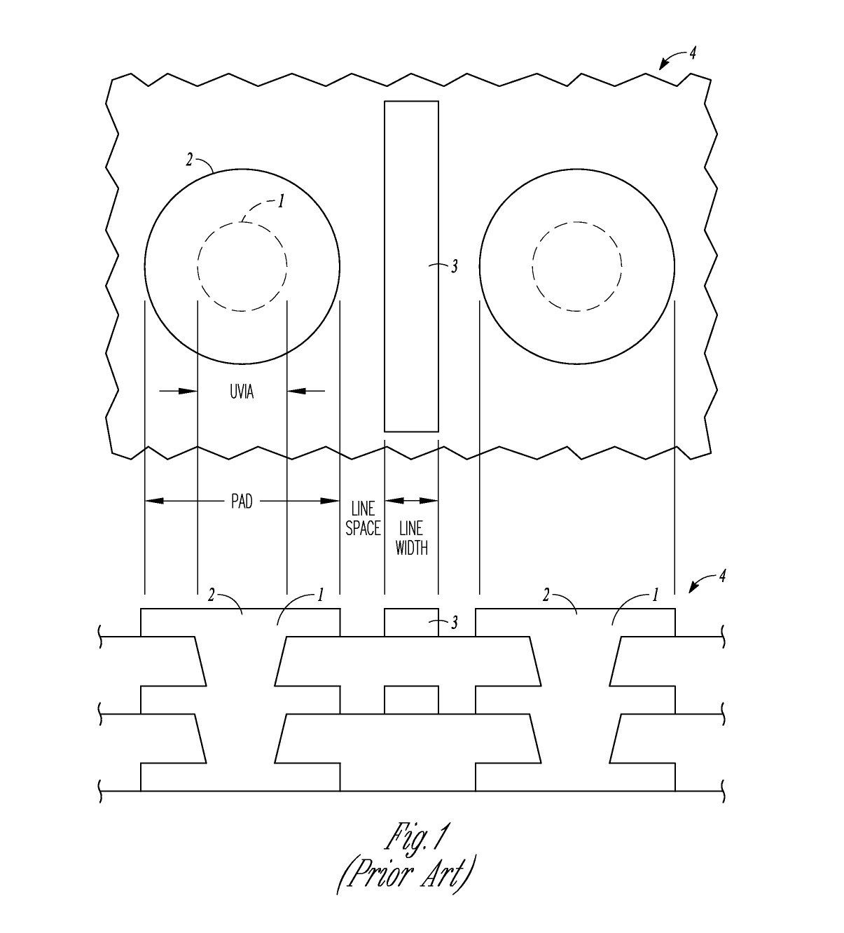

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Orientation terminology, such as “horizontal,” as used in this application is defined with respect to a plane parallel to the conventional plane or surface of a wafer or substrate, regardless of the orientation of the wafer or substrate. The term “vertical” refers to a direction perpendicular to the horizontal as defined above. Prepositions, such as “on,” “side” (as in “sidewall”), “higher,” “lower,” “over,” and “under” are defined with respect to the conventional plane or surface being on the top surface of the wafer or substrate, regardless of the orientation of the electrical interconnect or electronic package.

The electrical vias and methods described herein may enable the fabrication of electronic packages that include fine pitch electrical traces without changing the effective vertical interconnect area. In some forms, the electrical vias and methods described herein may be able to reduce one build up layer in the package thereby reducing the cost of fabricating an electronic package.

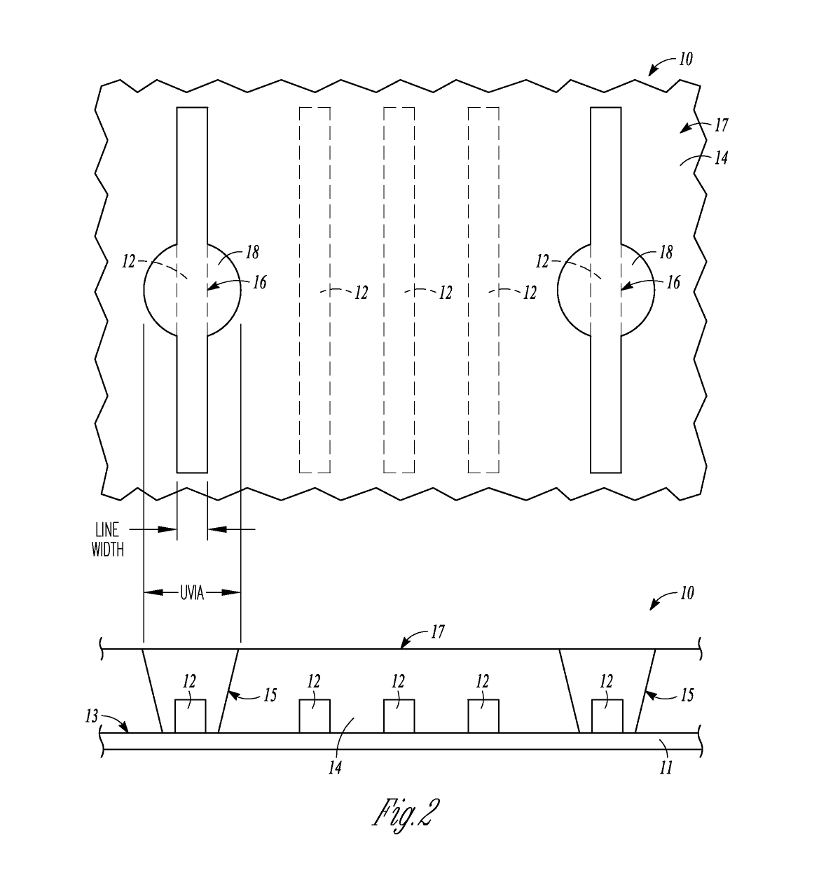

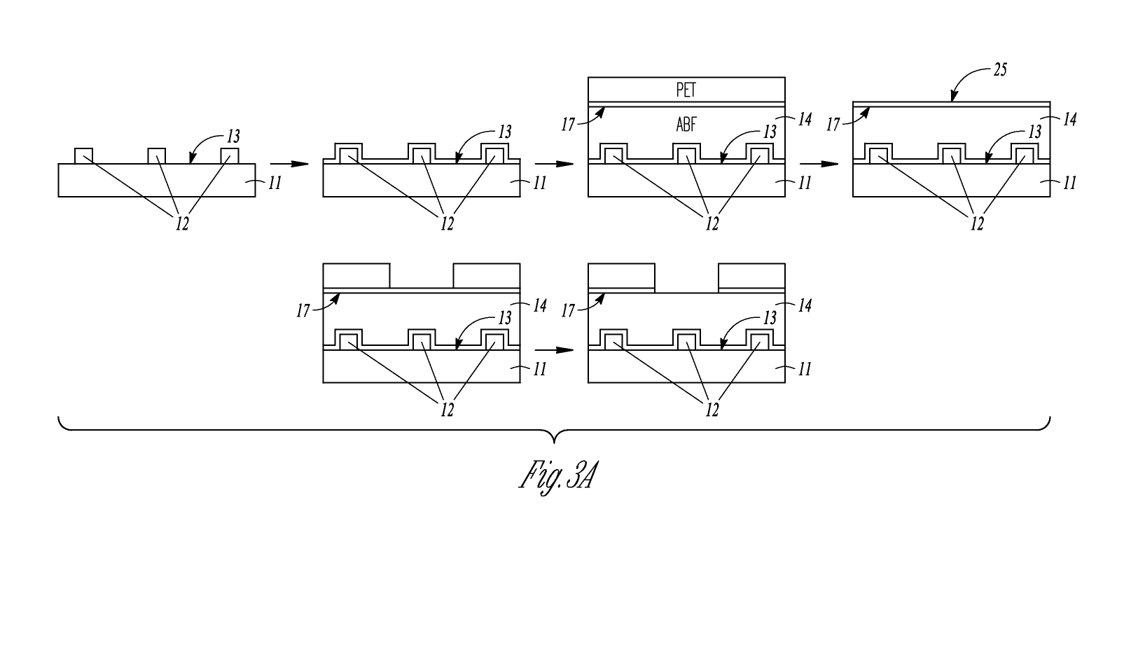

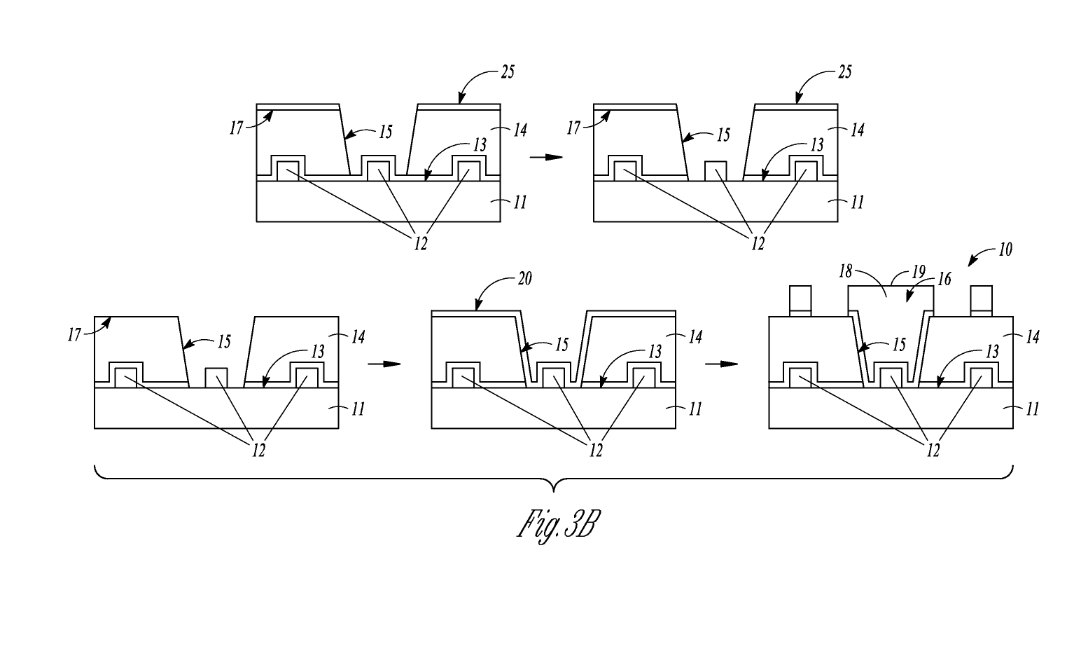

FIG. 2 shows a schematic top and side view illustrating a portion of an example electronic package 10. FIGS. 3A, 3B illustrate example steps for making an electronic package 10 similar to the electronic package 10 shown in FIG. 2. The electronic package 10 includes a first dielectric layer 11 that includes an electrical trace 12 formed on a surface 13 of the first dielectric layer 11.

The electronic package 10 further includes a second dielectric layer 14 on the surface 13 of the first dielectric layer 11. The second dielectric layer 14 includes an opening 15 such that the electrical trace 12 is within the opening 15.

The electronic package 10 further includes an electrical interconnect 16 that fills the opening 15 and extends above an upper surface 17 of the second dielectric layer 14. The electrically interconnect 16 is electrically connected to the electrical trace 12 on the first dielectric layer 11.

In the example forms that are illustrated in FIGS. 2, 3A, 3B, the electrical interconnect 16 includes a via 18 (e.g., a microvia) that fills the opening 15. The via 18 is electrically connected to the electrical trace 12 on the first dielectric layer 11 (sometimes through a layer 20 of electroless copper as shown in FIG. 3B).

In some forms, the electrical interconnect 16 includes a pad 19 that is electrically connected to the via 18 and extends above the upper surface 17 of the second dielectric layer 14. As an example, the via 18 may be integral with the pad 19.

It should be noted that although FIG. 2 shows the via 18 as being circular when viewed from above, the via 18 may be a variety of shapes. The type, size and shape of the via 18 will depend in part on the design of the electronic package 10 (among other factors).

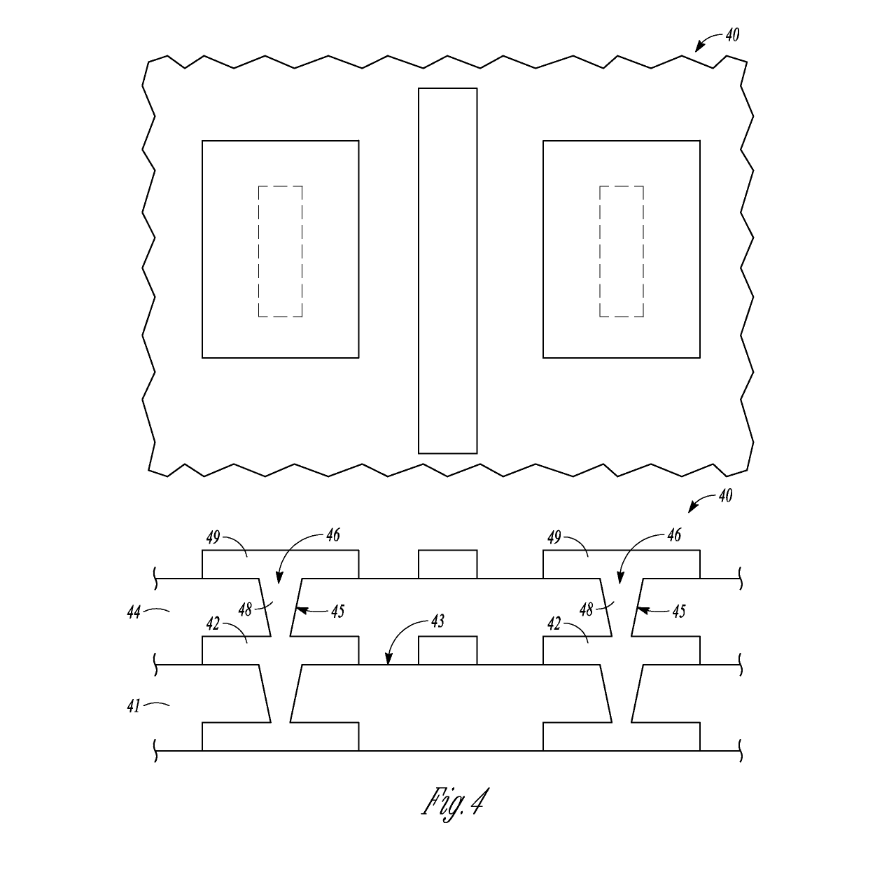

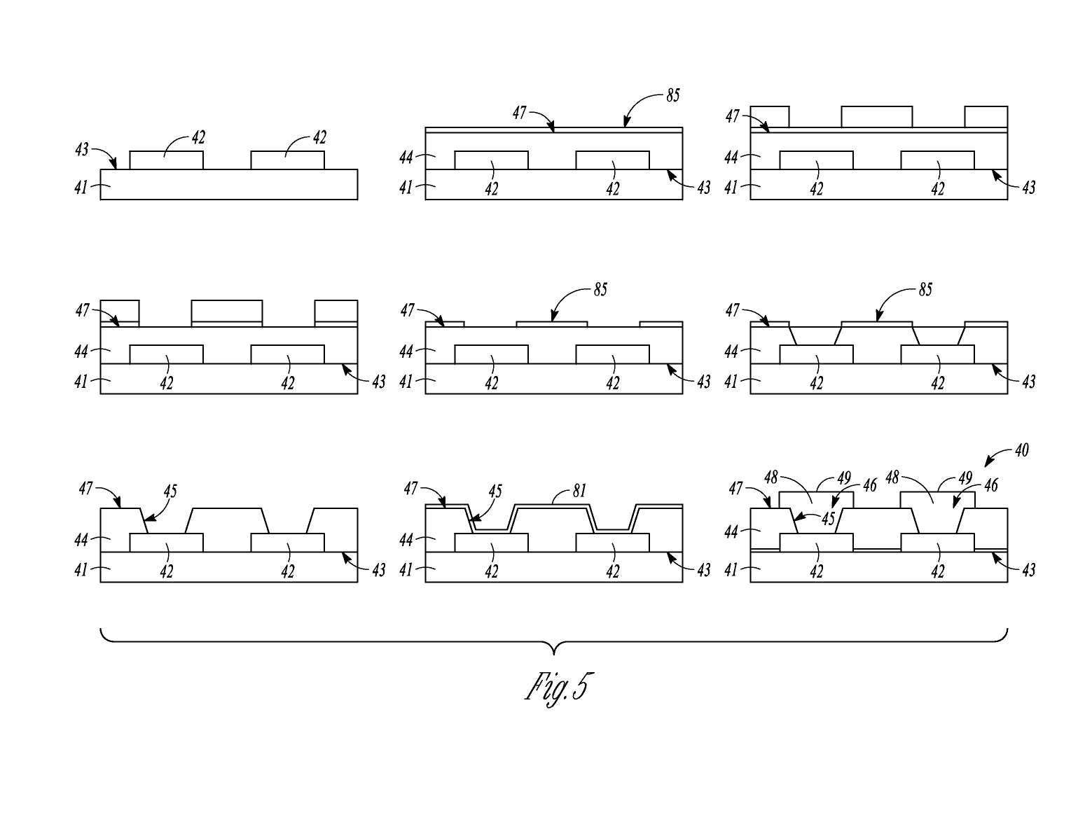

FIG. 4 shows a schematic top and side view illustrating a portion of an example electronic package 40. FIG. 5 illustrates example steps for making an electronic package 40 similar to the electronic package 40 shown in FIG. 4. The electronic package 40 includes a first dielectric layer 41 that includes a conductive pad 42 on a surface 43 of the first dielectric layer 41.

The electronic package 40 further includes a second dielectric layer 44 on the surface 43 of the first dielectric layer 41. The second dielectric layer 44 includes a non-circular opening 45 such that the conductive pad 42 is adjacent to the non-circular opening 45.

The electronic package 40 further includes a non-circular electrical interconnect 46 that fills the non-circular opening 45 and extends above an upper surface 47 of the second dielectric layer 44. The non-circular electrical interconnect 46 is electrically connected to the conductive pad 42 on the first dielectric layer 41.

In the example forms that are illustrated in FIGS. 4 and 5, the electrical interconnect 46 includes a non-circular via 48 that fills the non-circular opening 45. The non-circular via 48 is electrically connected to the conductive pad 42 on the first dielectric layer 41.

In some forms, the electrical interconnect 46 includes a non-circular pad 49 that is electrically connected to the non-circular via 48 and extends above the upper surface 47 of the second dielectric layer 44. As an example, the non-circular via 48 may be integral with the non-circular pad 49.

It should be noted that although FIG. 4 shows the non-circular via 48 and the non-circular pad 49 as being rectangular when viewed from above, the non-circular via 48 and the non-circular pad 49 may be a variety of shapes other than circular. As an example, the non-circular via 48 may be smaller than the non-circular pad 49.

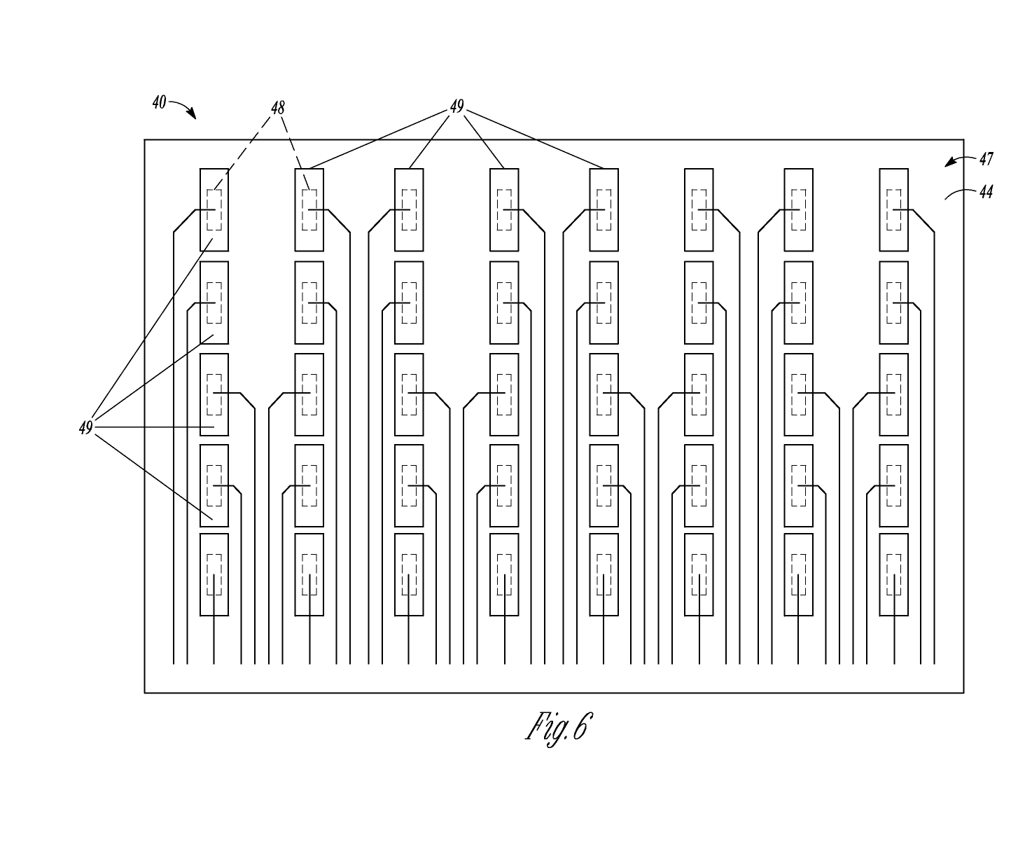

FIG. 6 shows a top view of a larger portion of the electronic package shown in FIGS. 4 and 5. As shown in FIGS. 4 and 6, the non-circular pad 49 may be longer and wider than the non-circular via 48. The type, size and shape of the non-circular via 48 and the non-circular pad 49 will depend in part on the design of the electronic package 40 (among other factors).

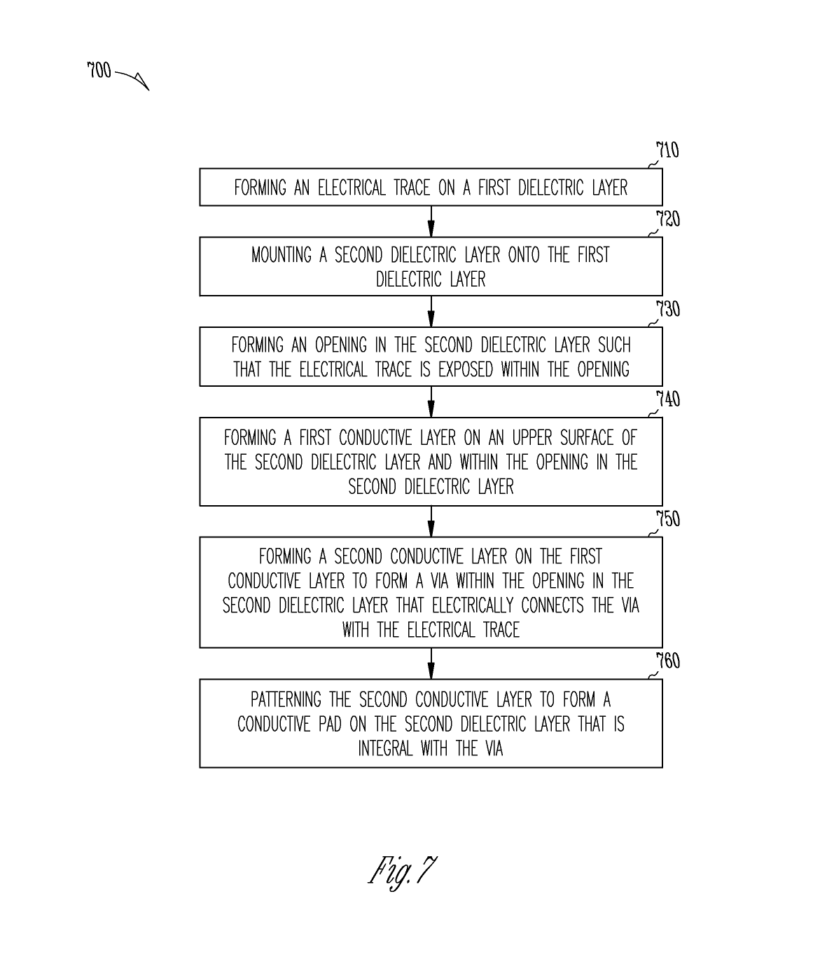

FIG. 7 is a flow diagram illustrating an example method [700] of forming an electronic package 10. The method [700] includes [710] forming an electrical trace 12 on a first dielectric layer 11 and [720] mounting a second dielectric layer 14 onto the first dielectric layer 11.

In some forms, [720] mounting a second dielectric layer 14 onto the first dielectric layer 11 may include mounting a second dielectric layer 14 that includes a metal mask to permit plasma etching of the second dielectric layer 14 in order to form the non-circular opening 15. As an example, the metal mask may be a copper mask that is formed using lithography techniques. The metal mask 25 defines the non-circular opening 15 and etching (e.g., flash etching) removes the copper mask. It should be noted that other methods of forming the non-circular opening 15 are contemplated.

The method [700] further includes [730] forming an opening 15 in the second dielectric layer 14 such that the electrical trace 12 is exposed within the opening 15. In some forms, plasma etching (e.g., a mixture of CF4 and O2 plasma) may be used to form opening 15 (e.g., microvias) in the second dielectric layer 14.

In addition, a silicon nitride thin film (see FIG. 3B) may be used as an etch stop to prevent the plasma etching from damaging the electrical trace 12. Silicon nitride may act as an electromigration barrier and a non-etching adhesion promoter layer. These properties may also be desirable for a variety of substrate architectures that require reduced conductive trace sizes and higher operating frequencies.

The method [700] further includes [740] forming a first conductive layer (see FIGS. 3A, 3B) on an upper surface 17 of the second dielectric layer 14 and within the opening 15 in the second dielectric layer 14. As an example, [740] forming a first conductive layer (see FIG. 3B) on an upper surface 17 of the second dielectric layer 14 may include electroless plating or sputtering (among other techniques that are known now or discovered in the future) a first conductive material on an upper surface 17 of the second dielectric layer 14 and within the opening 15 in the second dielectric layer 14.

The method [700] further includes [750] forming a second conductive layer (see FIG. 3B) on the first conductive layer to form a via 18 within the opening 15 in the second dielectric layer 14. The via 18 is electrically connected with the electrical trace 12. In some forms, [750] forming a second conductive layer on the first conductive layer may include electrolytic plating (among other techniques that are known now or discovered in the future) a second conductive material on the first conductive material. As an example, electrolytic plating a second conductive material on the first conductive material may include forming the via 18 within the opening 15 in the second dielectric layer 14 that is electrically connected to the electrical trace 12.

The method [700] further includes [760] patterning the second conductive layer to form a conductive pad 19 on the second dielectric layer 14 that is integral with the via 18. As an example, the conductive pad 19 may be fabricated in part by forming a patterned mask onto the second conductive material where the patterned mask is on the conductive pad 19.

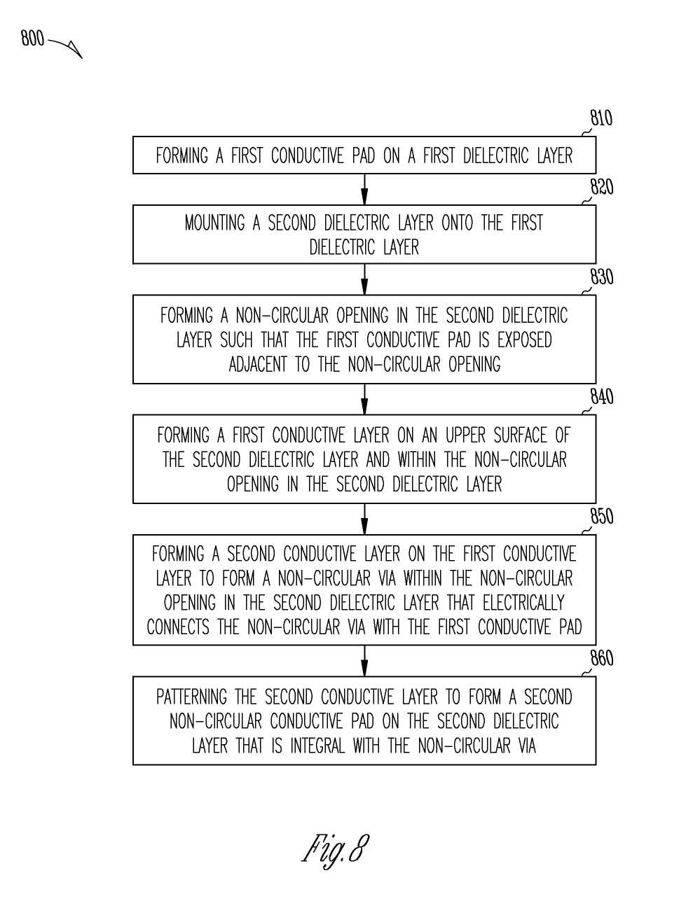

FIG. 8 is a flow diagram illustrating an example method [800] of forming an electronic package 40. The method [800] includes [810] forming a first conductive pad 42 on a first dielectric layer 41 and [820] mounting a second dielectric layer 44 onto the first dielectric layer 41.

The method [800] further includes [830] forming a non-circular opening 45 in the second dielectric layer 44 such that the first conductive pad 42 is exposed adjacent to the non-circular opening 45. In some forms, plasma etching may be used to form non-circular openings 45 in the second dielectric layer 44. When using plasma etching to form the non-circular opening 45, the size and shape of the non-circular opening 45 may only be limited by the resist resolution and the degree of anisotropy of the plasma etch so that the routing density might be increased significantly.

In addition, a silicon nitride thin film may be used as an etch stop to prevent the plasma etching from damaging the first conductive pad 42. Silicon nitride may act as an electromigration barrier and a non-etching adhesion promoter layer. These properties may be desirable for a variety of substrate architectures that require reduced size and higher operating frequencies.

The method [800] further includes [840] forming a first conductive layer 81 (see FIG. 5) on an upper surface 47 of the second dielectric layer 44 and within the non-circular opening 45 in the second dielectric layer 44. As an example, [840] forming a first conductive layer 81 on an upper surface 47 of the second dielectric layer 44 may include electroless plating or sputtering (among other techniques that are known now or discovered in the future) a first conductive material on an upper surface 47 of the second dielectric layer 44 and within the non-circular opening 45 in the second dielectric layer 44. The first conductive material is electrically connected to the first conductive pad 42.

The method [800] further includes [850] forming a second conductive layer on the first conductive layer 81 to form a non-circular via 48 within the non-circular opening 45 in the second dielectric layer 44. The non-circular via 48 is electrically connected with the first conductive pad 42.

In some forms, [850] forming a second conductive layer on the first conductive layer 81 may include electrolytic plating (among other techniques that are known now or discovered in the future) a second conductive material on the first conductive material. As an example, electrolytic plating a second conductive material on the first conductive material may include forming the non-circular via 48 within the non-circular opening 45 in the second dielectric layer 44 that is electrically connected to the first conductive pad 42.

The method [800] further includes [860] patterning the second conductive layer to form a non-circular second conductive pad 49 (see FIGS. 4 and 5) on the second dielectric layer 44 that is integral with the non-circular via 48. As an example, the non-circular second conductive pad 49 may be fabricated in part by forming a patterned mask onto the second conductive material where the patterned mask is on the second conductive pad 49.

In some forms, [820] mounting a second dielectric layer 44 onto the first dielectric layer 41 may include mounting a second dielectric layer 44 that includes a metal mask to permit plasma etching of the second dielectric layer 44 in order to form the non-circular opening 45. As an example, the metal mask may be a copper mask that is formed using lithography techniques. The metal mask 85 defines the opening 45 and etching (e.g., flash etching) removes the copper mask. It should be noted that other methods of forming the non-circular opening 45 are contemplated.

In some forms, [820] patterning the second conductive layer to form a second non-circular conductive pad 49 on the second dielectric layer 44 that is integral with the non-circular via 48 includes forming a second non-circular conductive pad 49 that is larger than the non-circular via 48. As an example, forming a second non-circular conductive pad 49 that is larger than the non-circular via 48 includes forming a second non-circular conductive pad 49 that is wider and longer than the non-circular via 48.

All vias 18, 48 and pads 19, 49 are subject to manufacturing variances during fabrication of the electronic packages 10, 40. The FIGS. show electronic packages 10, 40 that have been fabricated without any real misalignment between vias 18, 48 and pads 19, 49. The electronic packages 10, 40 described herein may be less sensitive to any vias 18, 48 and pads 19, 49 misalignment. The electronic packages 10, 40 and methods [700], [800] described herein may be used in a variety of applications.

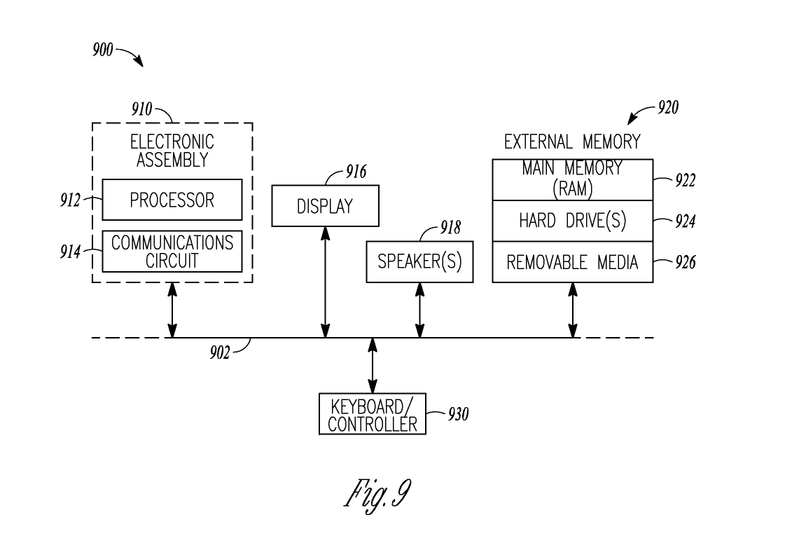

FIG. 9 is a block diagram of an electronic apparatus 900 incorporating at least one electronic package 10, 40 and/or method [700], [800] described herein. Electronic apparatus 900 is merely one example of an electronic apparatus in which forms of the electronic packages 10, 40 and/or methods [700], [800] described herein] may be used.

Examples of an electronic apparatus 900 include, but are not limited to, personal computers, tablet computers, mobile telephones, game devices, MP3 or other digital music players, etc. In this example, electronic apparatus 900 comprises a data processing system that includes a system bus 902 to couple the various components of the electronic apparatus 900. System bus 902 provides communications links among the various components of the electronic apparatus 900 and may be implemented as a single bus, as a combination of busses, or in any other suitable manner.

An electronic assembly 910 that includes any of the electronic packages 10, 40 and/or methods [700], [800] described herein as describe herein may be coupled to system bus 902. The electronic assembly 910 may include any circuit or combination of circuits. In one embodiment, the electronic assembly 910 includes a processor 912 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that may be included in electronic assembly 910 are a custom circuit, an application-specific integrated circuit (ASIC), or the like, such as, for example, one or more circuits (such as a communications circuit 914) for use in wireless devices like mobile telephones, tablet computers, laptop computers, two-way radios, and similar electronic systems. The IC can perform any other type of function.

The electronic apparatus 900 may also include an external memory 920, which in turn may include one or more memory elements suitable to the particular application, such as a main memory 922 in the form of random access memory (RAM), one or more hard drives 924, and/or one or more drives that handle removable media 926 such as compact disks (CD), flash memory cards, digital video disk (DVD), and the like.

The electronic apparatus 900 may also include a display device 916, one or more speakers 918, and a keyboard and/or controller 930, which can include a mouse, trackball, touch screen, voice-recognition device, or any other device that permits a system user to input information into and receive information from the electronic apparatus 900.

To better illustrate the method and apparatuses disclosed herein, a non-limiting list of embodiments is provided herein:

Example 1 includes an electronic package. The electronic package includes a first dielectric layer that includes an electrical trace formed on a surface of the first dielectric layer and a second dielectric layer on the surface of the first dielectric layer. The second dielectric layer includes an opening. The electrical trace is within the opening. The electronic package includes an electrical interconnect that fills the opening and extends above an upper surface of the second dielectric layer such that the electrically interconnect is electrically connected to the electrical trace on the first dielectric layer.

Example 2 includes the electronic package of example 1, wherein the electrical interconnect includes a via that fills the opening and is electrically connected to the electrical trace on the first dielectric layer.

Example 3 includes the electronic package of any one of examples 1-2, wherein the electrical interconnect includes a pad that is electrically connected to the via and extends above the upper surface of the second dielectric layer.

Example 4 includes the electronic package of any one of examples 1-3, wherein the via is integral with the pad.

Example 5 includes the electronic package of any one of examples 1-4, wherein the via is circular and the pad is circular.

Example 6 includes an electronic package that includes a first dielectric layer that includes a conductive pad formed on a surface of the first dielectric layer and a second dielectric layer on the surface of the first dielectric layer. The second dielectric layer includes a non-circular opening and the conductive pad is adjacent to the opening. The electronic package further includes a non-circular electrical interconnect that fills the non-circular opening and extends above the second dielectric layer. The non-circular electrical interconnect is electrically connected to the conductive pad.

Example 7 includes the electronic package of example 6, wherein the non-circular electrical interconnect includes a non-circular via that fills the non-circular opening and is electrically connected to the conductive pad on the first dielectric layer.

Example 8 includes the electronic package of any one of examples 6-7, wherein the non-circular electrical interconnect includes a non-circular conductive pad on the upper surface of the second dielectric layer, wherein the non-circular conductive pad is electrically connected to the non-circular via.

Example 9 includes the electronic package of any one of examples 6-8, wherein the non-circular via is smaller than the non-circular conductive pad.

Example 10 includes the electronic package of any one of examples 6-9, wherein the non-circular conductive pad is wider and longer than the non-circular via.

Example 11 includes a method. The method includes forming an electrical trace on a first dielectric layer and mounting a second dielectric layer onto the first dielectric layer. The method further includes forming an opening in the second dielectric layer such that the electrical trace is exposed within the opening and forming a first conductive layer on an upper surface of the second dielectric layer and within the opening in the second dielectric layer. The method further includes forming a second conductive layer on the first conductive layer to form a via within the opening in the second dielectric layer that electrically connects the via with the electrical trace and patterning the second conductive layer to form a conductive pad on the second dielectric layer that is integral with the via.

Example 12 includes the method of example 11, wherein forming a first conductive layer on an upper surface of the second dielectric layer includes electroless plating a first conductive material on an upper surface of the second dielectric layer and within the opening in the second dielectric layer, wherein the first conductive material is electrically connected to the electrical trace.

Example 13 includes the method of any one of examples 11-12, wherein forming a second conductive layer on the first conductive layer includes electrolytic plating a second conductive material on the first conductive material.

Example 14 includes the method of any one of examples 11-13, wherein electrolytic plating a second conductive material on the first conductive material includes forming the via within the opening in the second dielectric layer that is electrically connected to the electrical trace.

Example 15 includes the method of any one of examples 11-14, wherein mounting a second dielectric layer onto the first dielectric layer includes mounting a second dielectric layer that includes a metal mask to permit plasma etching of the second dielectric layer in order to form the opening.

Example 16 includes a method that includes forming a first conductive pad on a first dielectric layer and mounting a second dielectric layer onto the first dielectric layer. The method further includes forming a non- circular opening in the second dielectric layer such that the first conductive pad is exposed adjacent to the non-circular opening and forming a first conductive layer on an upper surface of the second dielectric layer and within the non-circular opening in the second dielectric layer. The method further includes forming a second conductive layer on the first conductive layer to form a non-circular via within the non-circular opening in the second dielectric layer that electrically connects the non-circular via with the first conductive pad and patterning the second conductive layer to form a second non-circular conductive pad on the second dielectric layer that is integral with the non-circular via.

Example 17 includes the method of example 16, wherein forming a first conductive layer on an upper surface of the second dielectric layer includes electroless plating the first conductive material on the upper surface of the second dielectric layer and within the non-circular opening in the second dielectric layer, wherein the first conductive material is electrically connected to the first conductive pad.

Example 18 includes the method of any one of examples 16-17, wherein forming a second conductive layer on the first conductive layer includes electrolytic plating a second conductive material on the first conductive material to form a non-circular via within the non-circular opening that electrically connects the electrical trace with the non-circular via.

Example 19 includes the method of any one of examples 16-18, wherein patterning the second conductive layer to form a second non-circular conductive pad that is integral with the non-circular via includes forming a second non-circular conductive pad that is larger than the non-circular via.

Example 20 includes the method of any one of examples 16-19, wherein forming a second non-circular conductive pad that is larger than the non-circular via includes forming a second non-circular conductive pad that is wider and longer than the non-circular via.

This overview is intended to provide non-limiting examples of the present subject matter. It is not intended to provide an exclusive or exhaustive explanation. The detailed description is included to provide further information about the methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. In addition, the order of the methods described herein may be in any order that permits fabrication of an electrical interconnect and/or package that includes an electrical interconnect. Other embodiments can be used, such as by one of ordinary skill in the art upon reviewing the above description.

The Abstract is provided to comply with 37 C.F.R. §1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An electronic package, comprising:
a first dielectric layer that includes an electrical trace formed on a surface of the first dielectric layer;
a second dielectric layer on the surface of the first dielectric layer, wherein the second dielectric layer includes an opening, wherein the electrical trace is within the opening; and
an electrical interconnect that fills the opening and extends above an upper surface of the second dielectric layer such that the electrical interconnect is electrically connected to the electrical trace on the first dielectric layer.

2. The electronic package of claim 1, wherein the electrical interconnect includes a via that fills the opening and is electrically connected to the electrical trace on the first dielectric layer.

3. The electronic package of claim 2, wherein the electrical interconnect includes a pad that is electrically connected to the via and extends above the upper surface of the second dielectric layer.

4. The electronic package of claim 3, wherein the via is integral with the pad.

5. The electronic package of claim 3, wherein the via is circular and the pad is circular.

6. An electronic package, comprising:
a first dielectric layer that includes a conductive pad formed on a surface of the first dielectric layer;
a second dielectric layer on the surface of the first dielectric layer, wherein the second dielectric layer includes a non-circular opening, wherein the conductive pad is adjacent to the opening;
a non-circular electrical interconnect that fills the non-circular opening and extends above the second dielectric layer, wherein the non-circular electrical interconnect is electrically connected to the conductive pad.

7. The electronic package of claim 6, wherein the non-circular electrical interconnect includes a non-circular via that fills the non-circular opening and is electrically connected to the conductive pad on the first dielectric layer.

8. The electronic package of claim 7, wherein the non-circular electrical interconnect includes a non-circular conductive pad on the upper surface of the second dielectric layer, wherein the non-circular conductive pad is electrically connected to the non-circular via.

9. The electronic package of claim 8, wherein the non-circular via is smaller than the non-circular conductive pad.

10. The electronic package of claim 9, wherein the non-circular conductive pad is wider and longer than the non-circular via.

11. A method comprising:
forming an electrical trace on a first dielectric layer;
mounting a second dielectric layer onto the first dielectric layer;
forming an opening in the second dielectric layer such that the electrical trace is exposed within the opening;
forming a first conductive layer on an upper surface of the second dielectric layer and within the opening in the second dielectric layer;
forming a second conductive layer on the first conductive layer to form a via within the opening in the second dielectric layer that electrically connects the via with the electrical trace; and
patterning the second conductive layer to form a conductive pad on the second dielectric layer that is integral with the via.

12. The method of claim 11, wherein forming a first conductive layer on an upper surface of the second dielectric layer includes electroless plating a first conductive material on an upper surface of the second dielectric layer and within the opening in the second dielectric layer, wherein the first conductive material is electrically connected to the electrical trace.

13. The method of claim 12, wherein forming a second conductive layer on the first conductive layer includes electrolytic plating a second conductive material on the first conductive material.

14. The method of claim 13, wherein electrolytic plating a second conductive material on the first conductive material includes forming the via within the opening in the second dielectric layer that is electrically connected to the electrical trace.

15. The method of claim 14, wherein mounting a second dielectric layer onto the first dielectric layer includes mounting a second dielectric layer that includes a metal mask to permit plasma etching of the second dielectric layer in order to form the opening.

16. A method comprising:
forming a first conductive pad on a first dielectric layer;
mounting a second dielectric layer onto the first dielectric layer;
forming a non-circular opening in the second dielectric layer such that the first conductive pad is exposed adjacent to the non-circular opening;
forming a first conductive layer on an upper surface of the second dielectric layer and within the non-circular opening in the second dielectric layer;
forming a second conductive layer on the first conductive layer to form a non-circular via within the non-circular opening in the second dielectric layer that electrically connects the non-circular via with the first conductive pad; and
patterning the second conductive layer to form a second non-circular conductive pad on the second dielectric layer that is integral with the non-circular via.

17. The method of claim 16, wherein forming a first conductive layer on an upper surface of the second dielectric layer includes electroless plating the first conductive material on the upper surface of the second dielectric layer and within the non-circular opening in the second dielectric layer, wherein the first conductive material is electrically connected to the first conductive pad.

18. The method of claim 17, wherein forming a second conductive layer on the first conductive layer includes electrolytic plating a second conductive material on the first conductive material to form a non-circular via within the non-circular opening that electrically connects the electrical trace with the non-circular via.

19. The method of claim 18, wherein patterning the second conductive layer to form a second non-circular conductive pad that is integral with the non-circular via includes forming a second non-circular conductive pad that is larger than the non-circular via.

20. The method of claim 19, wherein forming a second non-circular conductive pad that is larger than the non-circular via includes forming a second non-circular conductive pad that is wider and longer than the non-circular via.
